(19) United States
(12) Patent Application Publication
(10) Pub. No.: US 2022/0302729 A1
(43) Pub. Date: Sep. 22, 2022

(54) CHARGE DETERMINATION

(71) Applicant: Hewlett-Packard Development Company, L.P., Spring, TX (US)

(72) Inventors: Wei-Chih Huang, Taipei City (TW); Chih-Kai Chang, Taipei City (TW); Po Chin Chung, Taipei City (TW); Chao-Shen Chen, Taipei City (TW)

(73) Assignee: Hewlett-Packard Development Company, L.P., Spring, TX (US)

(21) Appl. No.: 17/635,559

(22) PCT Filed: Nov. 8, 2019
(86) PCT No.: PCT/US2019/060551

§ 371 Date: Feb. 15, 2022

(51) Int. Cl. H02J 7/00; G06F 1/28

(52) U.S. Cl. CPC H02J 7/00712; H02J 7/0048; G06F 1/28

(57) ABSTRACT

In some examples a computing device, comprising a battery, a processing resource and a memory resource storing non-transitory machine-readable instructions can cause the processing resource to determine a battery charge capacity of the battery, in response to the battery charge capacity being less than a threshold capacity, cause the battery to charge, and in response to the battery charge capacity being greater than the threshold capacity, compare the battery charge capacity of the computing device with a different battery charge capacity associated with a different computing device, and based on the comparison, cause a charge determination event to occur.

Battery charge capacity of a battery can be the charge stored by the battery. In some examples, the battery charge capacity may represent the maximum amount of energy that can be extracted from the battery under specified conditions.

### BRIEF DESCRIPTION OF THE DRAWINGS

FIG. 1 illustrates an example of a computing device suitable to determine charge of a battery consistent with the disclosure.

FIG. 2 illustrates an example flow chart for charge determination consistent with the disclosure.

FIG. 3 illustrates an example of computing device suitable to determine charge of a battery consistent with the disclosure.

FIG. 4 illustrates an example of a computing device suitable to determine charge of a battery consistent with the disclosure.

FIG. 5 illustrates a block diagram of a computing device suitable to determine charge of a battery consistent with the disclosure.

### DETAILED DESCRIPTION

A battery can provide power to a computing device. As described herein, the term “battery” refers to a device to store an electric charge. A computing device can charge and manage battery capacity of the computing device. For example, when a battery charge capacity of the computing device is low, the battery of the computing device can be charged. A computing device charging when the battery charge capacity is low can prevent the computing device from running out of power and abruptly shutting off, which may cause items to be lost, corrupted, etc. However, managing battery capacity in such a manner can increase power load of a plant and/or a network domain and can be expensive. For example, such computing devices may be charging during times when electricity may be more expensive, such as peak power times. Additionally, if many computing devices charge at the same time, a peak in power consumption may occur.

In some examples, the computing device can charge and manage battery capacity in a decentralized manner. As described herein, the term “decentralized” refers to delegating and/or distributing the task of charging and managing the battery from a local power source instead of a central power source. For example, a computing device (e.g., laptop, tablets, etc.) can manage battery charge capacity in a decentralized manner by self-monitoring the battery charge capacity of the battery. In some examples, a computing device can compare battery charge capacity against other computing devices' battery charge capacity and cause its battery to charge based on the comparison. Such decentralization can help reduce power load of a plant and/or domain from a central source.

In some examples, computing devices can be controlled via a central Information Technology (IT) management system. For example, a central IT management system may monitor peak hour activities and manage battery capacity based on activities performed during the peak hour. However, such a centralized system may increase total power consumption of a plant and/or domain and increase cost, as well as cost resources to operate.

Charge determination according to the disclosure, can allow for a computing device to determine when a charge determination event should occur. As described herein, the term “charge determination event” refers to an action and/or a prompt to charge a battery and/or delay charging a battery based on the battery charge capacity of the battery. For instance, the battery charge capacity can be compared with a threshold capacity to cause a charge determination event to occur.

As described herein, the term “threshold capacity” refers to a capacity that serves as a benchmark for comparison to cause an action. In some examples, a capacity above and/or below the threshold capacity can trigger a battery charge determination event. In some examples, the charge determination event can include delaying the battery from being charged when the battery capacity is more than a threshold capacity. In some examples, the charge determination event can include charging a battery when the battery capacity is less than a threshold capacity, as further described herein.

The charge event determination can be based on comparing a battery charge capacity of a computing device with a threshold capacity. Based on the comparison, in some examples, the battery charge capacity of a computing device can be compared with a different battery charge capacity associated with a different computing device. Based on the comparison, the computing device can cause the charge determination event to occur.

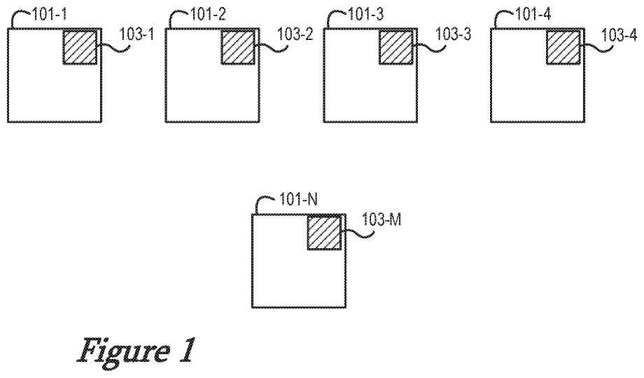

FIG. 1 illustrates an example of a computing device 101-1 suitable to determine charge of a battery consistent with the disclosure, Computing device 101-1 can include battery 103-1. Additionally shown in FIG. 1 are computing devices 101-2, 101-3, 101-4 and 101-N. Computing devices 101-2, 101-3, 101-4 and 101-N can include batteries 103-2, 103-3, 103-4, and 103-M respectively (referred to collectively herein as batteries 103).

Computing device 101-1 can include battery 103-1. The battery 103-1 can be a hardware component that can supply power to the computing device 101-1 to enable the computing device 101-1 to perform various tasks. Battery 103-1 can power the computing device 101-1 (e.g., a laptop computer) for an amount of time while the computing device 101-1 is disconnected from a power source. Batteries 103 can be rechargeable batteries that can be charged with electrical energy when connected to a power source.

Computing device 101-1 can determine a battery charge capacity of the battery 103-1. For example, the computing device 101-1 can determine that the battery charge capacity of the battery 103-1 is at 10%. As another example, the computing device 101-1 can determine that the battery charge capacity of the battery 103-1 is 80%.

The computing device 101-1 can compare the determined battery charge capacity of the battery 103-1 against a threshold capacity. The threshold capacity can be a predetermined capacity. For example, the threshold capacity can be 50%. The computing device 101-1 can compare the battery charge capacity of the battery 103-1 (e.g., 10%) with the threshold capacity of 50%.

In response to the battery charge capacity of the battery 103-1 being less than the threshold capacity, the computing device 101-1 can cause the battery 103-1 to charge. For example, the computing device 101-1 can determine that the battery charge capacity of the battery 103-1 is 10% and based on the determined battery charge capacity being less than the threshold capacity (e.g., 50%), cause the battery 103-1 to charge.

Although the threshold capacity is described above as being 50%, examples of the disclosure are not so limited. For example, the threshold capacity can be greater than 50% (e.g., 60%) or less than 50% (e.g., 40%). In some examples, the threshold capacity can be predetermined by a user (e.g., an IT manager or the like) based on the user's specification.

In some examples, the battery charge capacity of the battery 103-1 can be greater than the threshold capacity. In response to the battery charge capacity of the battery 103-1 being greater than the threshold capacity, the computing device 101-1 can compare the battery charge capacity of the battery 103-1 with a different battery charge capacity associated with a different computing device. For example, the computing device 101-1 can determine that the battery charge capacity of the battery 103-1 is 80% and based on the determined battery charge capacity being greater than the threshold capacity (e.g., 50%), compare the battery charge capacity with a different battery charge capacity associated with a different computing device 101 (e.g., the battery charge capacity of battery 103-2). Based on the comparison, the computing device 101-1 can cause a charge determination event to occur, as is further described herein.

As illustrated in FIG. 1, computing device 101-1 can be of a plurality of other computing devices (e.g., computing devices 101-2, 101-3, 101-4, 101-N). The computing device 101-1 can, in response to the battery charge capacity of the battery 103-1 being greater than the threshold capacity, rank the battery charge capacities of the batteries 103-1, 103-2, 103-3, 103-4, 103-M of computing devices 101-1, 101-2, 101-3, 101-4, respectively, having battery charge capacities being greater than the threshold capacity.

For instance, battery 103-1 can include a battery charge capacity of 80%, battery 103-2 can include a battery charge capacity of 60%, battery 103-3 can include a battery charge capacity of 73%, battery 103-4 can include a battery charge capacity of 90%, and battery 103-M can include a battery charge capacity of 45%. The computing device 101-1 can rank the battery charge capacities in order of battery charge capacity: battery 103-4 (e.g., 90%), battery 103-1 (e.g., 80%), battery 103-3 (e.g., 73%), and battery 103-2 (e.g., 60%). The computing device 101-1 can ignore ranking battery 103-M as it has a battery charge capacity of less than the threshold capacity (e.g., 50%).

Batteries can be organized into subsets according to the ranked battery charge capacities. For example, a first subset of ranked battery charge capacities can include those batteries having battery charge capacities being greater than a ranking threshold. The ranking threshold can be, for instance, 75%. Accordingly, batteries 103-1 and 103-4 can be included in the first subset of ranked battery charge capacities. Further, a second subset of ranked battery charge capacities can include those batteries having battery charge capacities being less than a ranking threshold. Accordingly, batteries 103-2 and 103-3 can be included in the second subset of ranked battery charge capacities.

In an example in which the battery charge capacity of battery 103-1 is in the second subset of ranked battery charge capacities (e.g., the battery charge capacity of battery 103-1 is 65%), the computing device 101-1 can delay charging of the battery.

As described above, the battery 103-1 can include a battery charge capacity of 80% and thus be included in the first subset of ranked battery charge capacities (e.g., those battery charge capacities being greater than a ranking threshold). As a result of the battery 103-1 being in the first subset of ranked battery charge capacities, the computing device 101-1 can cause the battery 103-1 to delay charging.

In some examples, battery 103-1 can include a battery charge capacity of 55%. Accordingly, the battery 103-1 can include a battery charge capacity being greater than the threshold charge capacity (e.g., 50%) but less than a ranking threshold (e.g., 75%). As a result, the battery 103-1 can be included in the second subset of ranked battery charge capacities.

In response to the battery 103-1 being in the second subset of ranked battery charge capacities, the computing device 101-1 can determine whether the battery charge capacity of battery 103-1 is equal to the battery charge capacities of any other computing devices in the second subset of ranked battery charge capacities (e.g., computing devices 101-2 and 101-3). For example, the computing device 101-1 can determine whether the battery charge capacity of battery 103-1 is equal to the battery charge capacities of either of batteries 103-2 and/or 103-3.

As described above, the battery charge capacities of batteries 103-2 and 103-3 can be 60% and 73%, respectively, and the battery charge capacity of battery 103-1 can be 55%. As a result, the computing device 101-1 can determine that the battery charge capacity of battery 103-1 is not equal to the battery charge capacities of the different batteries (e.g., 103-2, 103-3) included in the second subset of ranked battery charge capacities. Accordingly, the computing device 101-1 can cause the battery 103-1 to charge.

In some examples, battery 103-1 can include a battery charge capacity of 60%. Accordingly, the battery 103-1 can include a battery charge capacity being greater than the threshold charge capacity (e.g., 50%) but less than a ranking threshold (e.g., 75%), and can therefore be included in the second subset of ranked battery charge capacities. Further, in response to the battery 103-1 being in the second subset of ranked battery charge capacities, the computing device 101-1 can determine whether the battery charge capacity of battery 103-1 is equal to the battery charge capacities of any other computing devices in the second subset of ranked battery charge capacities (e.g., computing devices 101-2 and 101-3).

As described above, the battery charge capacities of batteries 103-2 and 103-3 can be 60% and 73%, respectively, and the battery charge capacity of battery 103-1 can be 60%. As a result, the computing device 101-1 can determine that the battery charge capacity of battery 103-1 is equal to the battery charge capacities of one of the different batteries (e.g., battery 103-2) included in the second subset of ranked battery charge capacities.

In response to the battery charge capacity of battery 103-1 being the equal battery charge capacity of the battery 103-2 (e.g., included in the second subset of ranked battery charge capacities), the computing device 101-1 can determine whether computing device 101-2 has asserted a charge token. As described herein, the term “charge token” refers to an object representing information. For example, the charge token can be an object representing an intention to charge a battery.

In some examples, the computing device 101-1 can determine that the computing device 101-2 has asserted a charge token. In response, the computing device 101-1 can delay charging the battery 103-1.

In some examples, the computing device 101-1 can determine that the computing device 101-2 has not asserted a charge token. In response, the computing device 101-1 can cause the battery 103-1 to charge.

As described above, the computing device 101-1 can cause the battery 103-1 to charge in various instances. In such instances, the computing device 101-1 can cause the battery 103-1 to charge for a predetermined amount of time. The predetermined amount of time can be 10 minutes, although examples of the disclosure are not limited to 10 minutes. For example, the predetermined amount of time can be longer than 10 minutes or shorter than 10 minutes and can be configurable.

After the predetermined amount of time, the computing device 101-1 can stop charging the battery 103-1. For example, the computing device 101-1 can stop charging the battery 103-1 after 10 minutes.

The computing device 101-1 can determine the battery charge capacity of the battery 103-1 according to a predetermined time interval. For example, the computing device 101-1 can determine that the battery charge capacity be checked every 10 minutes. In some examples, the computing device 101-1 can determine the frequency of the battery charge capacity be checked based on the last recorded battery charge capacity. For example, the computing device 101-1 can determine the battery charge capacity be checked at a 30-minute interval when the battery charge capacity is between 40%-100%. When the battery charge capacity drops under the 40% mark, the computing device 101-1 can determine the charge capacity to be checked every 10 minutes. In other words, in some examples, the computing device 101-1 can determine the battery charge capacity of the battery 103-1 at a frequency that is based on the previously recorded battery charge capacity, where the battery charge capacity is determined more frequently when the battery charge capacity is below a threshold charge capacity and less frequently when the battery charge capacity is above a threshold charge capacity.

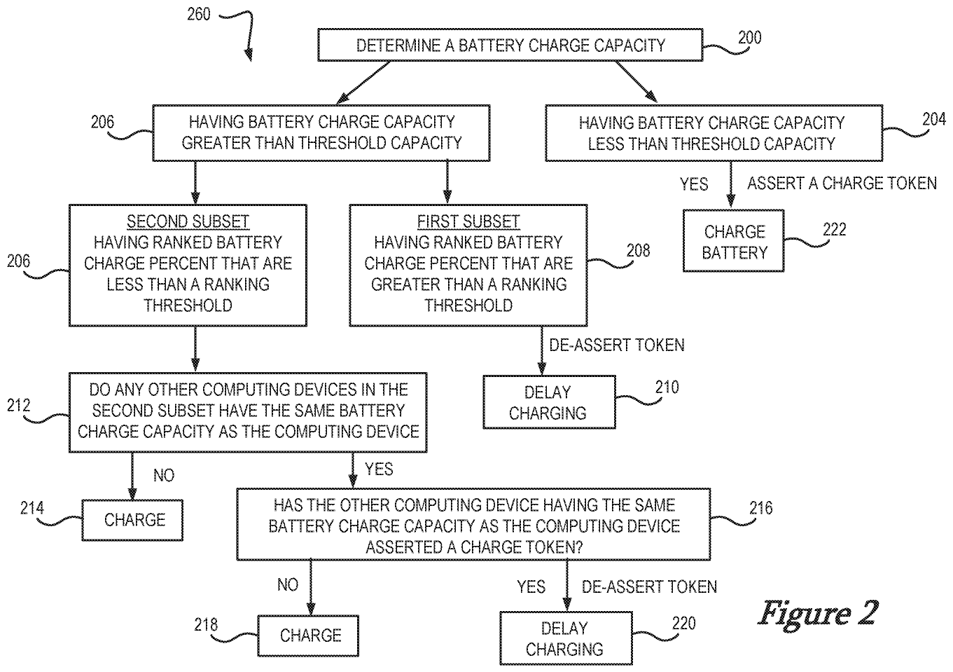

FIG. 2 illustrates an example flow chart 26—for charge determination consistent with the disclosure. At 200, a computing device (e.g., computing device 101-1, described in connection with FIG. 1) can determine a battery charge capacity of its battery. For example, the computing device can determine that the battery charge capacity of its battery is at 20%. The computing device can compare the determined battery charge capacity of the battery against a predetermined threshold capacity. In some examples, the computing device can determine the battery charge capacity of the battery is less than a threshold capacity. In some examples, the computing device can determine the battery charge capacity of the battery is greater than the threshold capacity, and in such an instance compare the battery charge capacity against a battery charge capacity of different computing device(s). Based on the comparison, the computing device can cause a charge determination event to occur, as is further described herein.

At 204, the computing device can determine that the battery charge capacity of the battery is less than the threshold capacity. The computing device can compare the determined battery charge capacity of the battery (e.g., 10%) with the threshold capacity of 50% and determine the charge capacity to be less than the threshold capacity.

At 222, computing device can, in response to the battery charge capacity being less than the threshold capacity, cause the battery to charge. For example, the computing device can determine that the battery charge capacity of the battery is 10% and based on the determined battery charge capacity being less than the threshold capacity (e.g., 50%), cause the battery to charge. The computing device can cause the battery to charge for a predetermined amount of time. For instance, based on the determined battery charge capacity being less than the threshold capacity, the computing device can cause the battery to charge for 10 minutes.

At 202, the computing device can determine that the battery charge capacity of the battery is greater than the threshold capacity. In response to the battery charge capacity being greater than the threshold capacity, the computing device can compare the battery charge capacity of the computing device with different battery charge capacity (e.g., 103-2, 103-3, 103-3, 103-4, and 103-N as described in FIG. 1) associated with a different computing device (e.g., 101-2, 101-3, 101-3, 101-4, and 101-M as described in FIG. 1).

The computing device can rank the battery charge capacities of other computing devices that have battery charge capacities that are greater than the threshold capacity in order of battery charge capacity. For example, the computing device can rank battery charge capacities as: a first battery (e.g., 90%), a second battery (e.g., 80%), a third battery (e.g., 73%), and a fourth battery (e.g., 60%).

Batteries can be organized into subsets according to the ranked battery charge capacities. For example, a first subset of ranked battery charge capacities can include those batteries having battery charge capacities that are greater than the threshold capacity and greater than a ranking threshold. The ranking threshold can be, for instance, 75%. Accordingly, the first battery and the second battery can be included in the first subset of ranked battery charge capacities since the first and the second batteries have battery charge capacity greater than 75%.

A second subset of ranked battery charge capacities can include those batteries having battery charge capacities less than a ranking threshold. Accordingly, the third battery and the fourth battery can be included in the second subset of ranked battery charge capacities since the third and the fourth batteries have battery charge capacities less than 75%.

As described above, the first battery can include a battery charge capacity of 90% and thus be above the threshold capacity (e.g., 50%) and a ranking threshold (e.g., 75%). Accordingly, the first battery can be included in the first subset of ranked battery charge capacities.

At 208, the computing device can determine that the battery charge capacity of the first battery is included in the first subset of ranked battery charge capacities. For example, the computing device can determine that the battery charge capacity of the first battery is 90%. Since the battery charge capacity of the first battery (e.g., 90%) is greater than the ranking threshold (e.g., 75%) and the threshold capacity (e.g., 50%), the computing device can determine the first battery is in the first subset of ranked battery charge capacities. At 210, the computing device can delay the first battery from being charged based on the determination that the first battery is included in the first subset of the ranked batteries. The computing device can delay the battery from being charged for a predetermined amount of time.

In an example in which the battery charge capacity of the computing device is determined to be 60%, the computing device can, at 206, determine that the battery charge capacity of the first battery is included in the second subset of ranked battery charge capacities. For example, the battery charge capacity of the first battery can be greater than the threshold capacity (e.g., 50%) but less than the ranking threshold (e.g., 75%), and as such be included in the second subset of ranked battery charge capacities.

At 212, the computing device can determine whether the battery charge capacity of the first battery is equal to the battery charge capacities of any other computing devices in the second subset of ranked battery charge capacities. For example, battery charge capacity of the first battery can be equal to the battery charge capacity of the fourth battery (e.g., 60%).

At 216, in response to the computing device determining that battery charge capacity of the battery (e.g., 60%) is equal to the battery charge capacity of a different battery (e.g., the fourth battery of 60%) included in the second subset of ranked battery charge capacities, the computing device can determine whether the other computing device has asserted a charge token . . . .

At 218, the computing device can charge the battery in response to determining the other computing device did not assert a charge token.

At 220, computing device can de-assert the charge token and delay charging the battery in response to determining the other computing device did assert a charge token.

In an example in which the battery charge capacity of the computing device is determined to be 55%, the computing device can, at 206, determine that the battery charge capacity of the first battery is included in the second subset of ranked battery charge capacities. For example, the battery charge capacity of the first battery can be greater than the threshold capacity (e.g., 50%) but less than the ranking threshold (e.g., 75%), and as such be included in the second subset of ranked battery charge capacities. At 212, the computing device can determine whether the battery charge capacity of the first battery is equal to the battery charge capacities of any other computing devices in the second subset of ranked battery charge capacities. The computing device can determine that battery charge capacity of the battery (e.g., 55%) is not equal to the battery charge capacity of any other batteries in the second subset of ranked battery charge capacities (e.g., 73% or 60%). At 214, the computing device can charge the battery in determination that the charge capacity of the battery is not the same as the battery charge capacity of any other batteries in the second subset ranked battery charge capacities. The computing device can charge the battery for a predetermined amount of time.

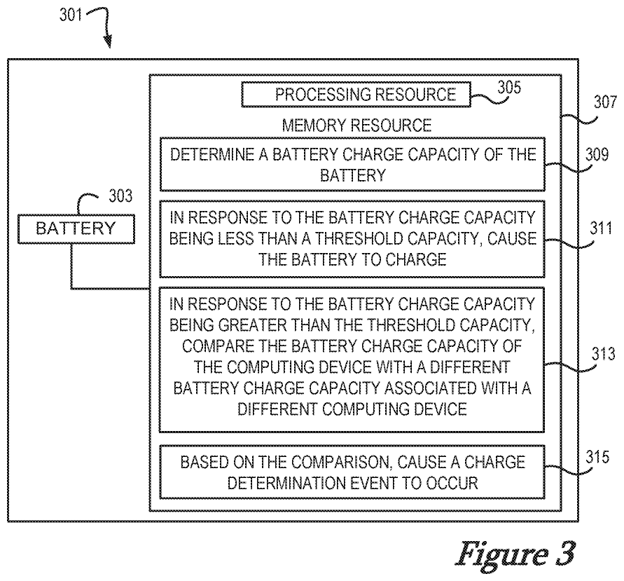

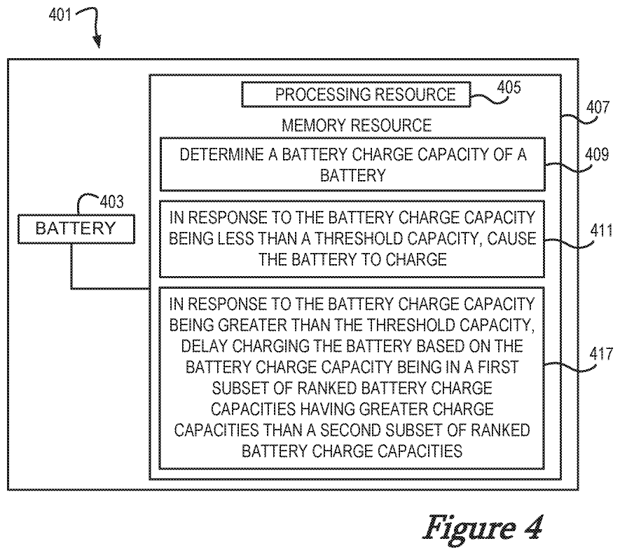

FIG. 3 illustrates an example of computing device 301 suitable to determine charge of a battery consistent with the disclosure, Computing device 301 can include battery 303 and processing resource 305, communicatively coupled to a memory resource 307 on which instructions may be stored, such as instructions 309, 311, 313, and 315. As described herein, the term “processing resource” refers to a central processing unit (CPU), microprocessor, and/or other hardware device suitable for retrieval and execution of instructions stored in a memory resource. Processing resource 305 may be a central processing unit (CPU), microprocessor, and/or other hardware device suitable for retrieval and execution of instructions stored in memory resource 307. The processing resource 305 may fetch, decode, and execute stored instructions to perform actions related to charge determination. Processing resource 305 and memory resource 307 can be analogous to the processing resource 405 and memory resource 07, as described in FIG. 4.

Instructions 309, when executed by a processing resource such as the processing resource 305, can cause the processing resource 305 to determine a battery charge capacity of the battery of the computing device 301. For example, the processing resource 305 can determine that the battery charge capacity of the battery 303 is 40%. The battery charge capacity can be compared against a threshold capacity.

Instructions 311, when executed by a processing resource such as the processing resource 305, can cause the processing resource 305 to, in response to the battery charge capacity being less than a threshold capacity, cause the battery 303 of the computing device 301 to charge. For example, the processing resource 305 can determine the battery charge capacity of the battery 303 is less than a threshold capacity (e.g., 50%), and in response can cause the battery 303 of the processing resource 305 to charge.

Instructions 313, when executed by a processing resource such as the processing resource 305, can cause the processing resource 305 to, in response to the battery charge capacity being greater than the threshold capacity, compare the battery charge capacity of the computing device with a different battery charge capacity associated with a different computing device. For example, computing device 301 can compare battery charge capacity of the computing device 301 with battery charge capacity of a different battery associated with a different computing device.

Instructions 315, when executed by a processing resource such as the processing resource 305, can cause the processing resource 305 to, based on the comparison, cause a charge determination event to occur.

FIG. 4 illustrates an example of computing device 401 suitable to determine charge of a battery 403 consistent with the disclosure. Computing device 401 can include battery 403, Computing device 401 can include a processing resource 405 and a memory resource 407. As described herein, the computing device 401 can perform a number of functions related to charge determination of a battery. Processing resource 405 can be a central processing unit (CPU), a semiconductor-based micro processing resource, and/or other hardware devices suitable for retrieval and execution of instructions, stored in memory resource 407. Processing resource 405 can retrieve and execute instructions 409, 411, and 417 stored in memory resource 407.

Processing resource 405 can be a central processing unit (CPU), a semiconductor based micro processing resource, and/or other hardware devices suitable for retrieval and execution of machine-readable instructions, stored in memory resource 407. As an alternative or in addition to retrieving and executing instructions 409, 411, 417, the processing resource 405 can include a plurality of electronic circuits that include electronic components for performing the functionality of instructions 409, 411, and 417.

Memory resource 407 can be any electronic, magnetic, optical, or other physical storage device that stores executable instructions and/or data. Thus, memory resource 407 can be, for example, Random Access Memory (RAM), an Electrically-Erasable Programmable Read-Only Memory (EEPROM), a storage drive, an optical disc, and the like. Memory resource 407 can be disposed within the computing device 401, as shown in FIG. 4. Additionally, and/or alternatively, memory resource 407 can be a portable, external or remote storage medium, for example, that allows the computing device 401 to download the instructions from a portable/external/remote storage medium, Computing device 404 and battery 403 can be analogous to computing device 101-1 and battery 103-1, respectively, as described in relation to FIG. 1.

Instructions 409, when executed by a processing resource such as the processing resource 405, can cause the processing resource 405 to determine a battery charge capacity of the battery 403 of the computing device 401. For example, the processing resource 405 can determine that the battery charge capacity of the battery 403 is 80%. In other examples, computing device 401 can determine that the battery charge capacity of the battery 403 is 35%, 49%, 70%, etc.

The battery charge capacity can be compared against a threshold capacity (e.g., 50%). In some examples, the battery charge capacity of the battery 403 can a charge capacity that is less than the threshold capacity, as is further described herein. In some examples, the battery charge capacity of the battery 403 can be a battery charge capacity that is greater than the threshold capacity, as is further described herein.

Instructions 411, when executed by a processing resource such as the processing resource 405, can cause the processing resource 405 to, in response to the battery charge capacity being less than a threshold capacity, cause the battery 403 to charge. For example, the computing device 404 can determine that the battery charge capacity of the battery 403 is 10%. The determined battery charge capacity of the battery 403 (e.g., 10%) can be compared against the threshold capacity (e.g., 50%), and in response to the battery charge capacity of the battery 403 being 10%, which is less than 50%, the computing device 401 cause the battery 403 to charge.

Instructions 417, when executed by a processing resource such as the processing resource 405, can cause the processing resource 405 to, in response to the battery charge capacity being greater than the threshold capacity, delay charging the battery based on the battery charge capacity being in a first subset of ranked battery charge capacities having greater charge capacities than a second subset of ranked battery charge capacities.

For example, the computing device 401 can, in response to the battery charge capacity of the battery 403 being greater than the threshold capacity, rank the battery charge capacity of the battery 403 and battery charge capacities of different batteries of different computing devices having battery charge capacities being greater than the threshold capacity.

Batteries can be organized into subsets according to the ranked battery charge capacities. A first subset of ranked battery charge capacities can include computing devices having battery charge capacities being greater than a ranking threshold and a second subset of ranked battery charge capacities can include computing devices having battery charge capacities being less than the ranking threshold. For example, batteries with a battery charge capacity above a threshold capacity (e.g., 50%) and above a ranking threshold (e.g., 80%) can be included in a first subset of ranked threshold battery charge capacities. If the battery 403 is determined to be in the first subset of ranked battery charge capacities, the computing device 401 can cause the battery 403 to delay charging.

The second subset of ranked battery charge capacities includes computing devices having battery charge capacities being less than a ranking threshold. For example, a second subset of ranked battery charge capacities can include those batteries having battery charge capacities above a threshold capacity (e.g., 50%) and less than the ranking threshold (e.g. 75%). Accordingly, if the battery charge capacity of battery 403 is 65%, the battery 403 can be included in the second subset of the ranked battery charge capacities.

In some examples, based on the comparison, the computing device 401 can cause a charge determination event to occur. The charge determination event can include delaying the battery 403 from being charged. In some examples, based on the comparison, the computing device 401 can cause the battery 403 to charge.

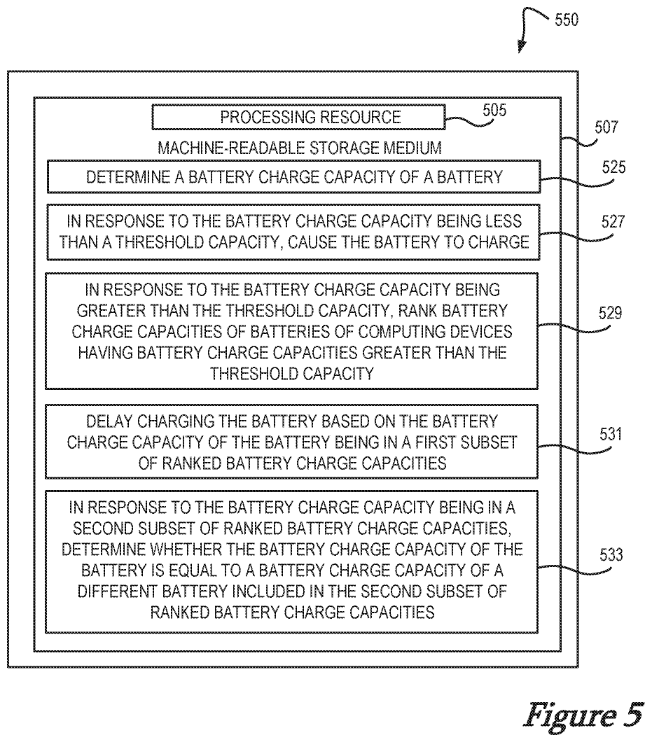

FIG. 5 illustrates a block diagram of a computing device 550 suitable to determine charge of a battery consistent with the disclosure. Computing device 550 can determination can include a processing resource 505, communicatively coupled to a non-transitory machine readable storage medium 507 on which instructions may be stored, such as instructions 525, 527, 529, 531, and 533. Processing resource 505 can be analogous to processing resource 105 and 305 described in relation to FIG. 1 and FIG. 3, respectively. Non-transitory machine readable 507 can be analogous to memory resource 307 described in relation to FIG. 3. Computing device 550 can include a battery (not shown in FIG. 5) analogous to battery 103, 303, and 403, as described in respect to FIGS. 1, and 3, respectively.

As used herein, “communicatively coupled” can include coupled via various wired and/or wireless connections between devices such that data can be transferred in various directions between the devices. Although the following descriptions refer to a processing resource and a memory resource, the descriptions may also apply to a system and/or computing device with multiple processing resources and multiple memory resources. In such examples, the instructions may be distributed (e.g., stored) across multiple non-transitory machine readable storage media and the instructions may be distributed (e.g., executed by) across multiple processing resources. Processing resource 505 can be analogous processing resource 305 and 405 described in relation to FIG. 3 and FIG. 4, respectively.

Instructions 525, when executed by a processing resource such as the processing resource 505, can include instruction to determine a battery charge capacity of the battery of the computing device 550. For example, the computing device 501 can determine that the battery charge capacity of the battery 403 is 40%. The battery charge capacity can be compared against a threshold capacity.

Instructions 527 when executed by a processing resource such as the processing resource 505, can include instructions to, in response to the battery charge capacity being less than a threshold capacity, cause the battery of the computing device 550 to charge. For example, processing resource 505 can include instruction to determine that the battery charge capacity of the computing device is 10%. The determined battery charge capacity of the battery being less than a threshold capacity (e.g., 50%), can cause the battery of the computing device 550 to charge.

Instructions 529 when executed by a processing resource such as the processing resource 505, can include instructions to, in response to the battery charge capacity being greater than the threshold capacity, rank battery charge capacities of batteries of computing devices having battery charge capacities being greater than the threshold capacity. Ranked batteries can be organized into subsets according to battery charge capacities of the batteries.

Instructions 531, when executed by a processing resource such as the processing resource 505, can cause the processing resource 505 to delay charging the battery based on the battery charge capacity of the battery being in a first subset of ranked battery charge capacities. The first subset of ranked battery charge capacities can include computing devices having battery charge capacities being greater than a ranking threshold. For example, batteries with a battery charge capacity above a threshold capacity (e.g., 50%) and above a ranking threshold (e.g., 80%) can be determined to be included in the first subset of ranked threshold battery charge capacities. In response to the battery of the computing device 550 being determined to be in the first subset of ranked battery charge capacities, the processing resource 505 can delay charging the battery.

Instructions 533, when executed by a processing resource such as the processing resource 505, can cause the processing resource 505 to, in response to the battery charge capacity of the battery being in a second subset of ranked battery charge capacities, determine whether the battery charge capacity of the battery is equal to a battery charge capacity of a different battery included in the second subset of ranked battery charge capacities. The second subset of ranked battery charge capacities can include computing devices having battery charge capacities being less than a ranking threshold. In some examples, in response to the battery being in the second subset of ranked battery charge capacities, the computing device 550 can determine whether the battery charge capacity of the battery is equal to the battery charge capacities of any other computing devices in the second subset of ranked battery charge capacities

In response to the battery charge capacity of the battery being equal to a battery charge capacity of a different battery included in the second subset of ranked battery charge capacities and in response to an absence of a charge token assertion by a the computing device having the different battery, the processing resource 505 can cause the battery of the computing device to charge.

In response to the battery charge capacity of the battery being equal to a battery charge capacity of the different battery included in the second subset of ranked battery charge capacities and the computing device having the different battery has asserted a charge token, the processing resource 505 can cause the battery of the computing device to delay charging.

The above specification, examples and data provide a description of the method and applications, and use of the system and method of the disclosure. Since many examples can be made without departing from the spirit and scope of the system and method of the disclosure, this specification merely sets forth some of the many possible example configurations and implementations.

The figures herein follow a numbering convention in which the first digit corresponds to the drawing figure number and the remaining digits identify an element or component in the drawing. For example, reference numeral 101 can refer to element 101 in FIG. 1 and an analogous element can be identified by reference numeral 301 in FIG. 3, Elements shown in the various figures herein can be added, exchanged, and/or eliminated to provide additional examples of the disclosure. In addition, the proportion and the relative scale of the elements provided in the figures are intended to illustrate the examples of the disclosure, and should not be taken in a limiting sense.

It can be understood that when an element is referred to as being “on,” “connected to”, “coupled to”, or “coupled with” another element, it can be directly on, connected, or coupled with the other element or intervening elements can be present. In contrast, when an object is “directly coupled to” or “directly coupled with” another element it is understood that are no intervening elements (adhesives, screws, other elements), etc.

What is claimed:

1. A computing device, comprising:
a battery;
a processing resource;
a memory resource storing non-transitory machine-readable instructions to cause the processing resource to:
determine a battery charge capacity of the battery;
in response to the battery charge capacity being less than a threshold capacity cause the battery to charge;
in response to the battery charge capacity being greater than the threshold capacity, compare the battery charge capacity of the computing device with a different battery charge capacity associated with a different computing device; and
based on the comparison, cause a charge determination event to occur.

2. The computing device of claim 1, wherein the charge determination event includes delaying the battery from being charged.

3. The computing device of claim 2, wherein the processing resource is to delay the battery from being charged for a predetermined amount of time.

4. The computing device of claim 1, wherein the processing resource is to compare, in response to the battery charge capacity being greater than the threshold capacity, the battery charge capacity against ranked battery charge capacities of other computing devices having battery charge capacities greater than the threshold capacity.

5. The computing device of claim 4, wherein the processing resource is to determine whether to charge the battery based on the comparison.

6. The computing device of claim 5, wherein in response to the comparison determining that the battery is to be charged, the processing resource is to cause the battery to charge for a predetermined amount of time.

7. A computing device, comprising:
a processing resource;
a memory resource storing non-transitory machine-readable instructions to cause the processing resource to:
determine a battery charge capacity of a battery f the computing device;
in response to the battery charge capacity being less than a threshold capacity, cause the battery to charge; and
in response to the battery charge capacity being greater than the threshold capacity, delay charging the battery based on the battery charge capacity being in a first subset of ranked battery charge capacities having greater charge capacities than a second subset of ranked battery charge capacities.

8. The computing device of claim 7, wherein the first subset of ranked battery charge capacities includes computing devices having battery charge capacities being greater than a ranking threshold.

9. The computing device of claim 7, wherein:
in response to the battery charge capacity being greater than the threshold capacity and the battery charge capacity is in the second subset of ranked battery charge capacities, delay charging of the battery; and
the second subset of ranked battery charge capacities includes computing devices having battery charge capacities being less than a ranking threshold.

10. The computing device of claim 7, wherein the computing device is to determine the battery charge capacity according to a predetermined time interval.

11. A non-transitory computer readable medium storing instructions executable by a processing resource to cause the processing resource to:
determine a battery charge capacity of a battery of a computing device;
in response to the battery charge capacity being less than a threshold capacity, cause the battery to charge; and
in response to the battery charge capacity being greater than the threshold capacity:
rank battery charge capacities of batteries of computing devices having battery charge capacities being greater than the threshold capacity;
delay charging the battery based on the battery charge capacity of the battery being in a first subset of ranked battery charge capacities; and
in response to the battery charge capacity of the battery being in a second subset of ranked battery charge capacities, determine whether the battery charge capacity of the battery is equal to a battery charge capacity of a different battery included in the second subset of ranked battery charge capacities.

12. The medium of claim 11, wherein:
in response to the battery charge capacity of the battery being equal to battery charge capacity of the different battery included in the second subset of ranked battery charge capacities; and
in response to an absence of a charge token assertion by a computing device having the different battery, charge the battery of the computing device.

13. The medium of claim 11, wherein in response to the battery charge capacity of the battery being equal to battery charge capacity of the different battery included in the second subset of ranked battery charge capacities and a computing device having the different battery has asserted a charge token, delay charging of the battery of the computing device.

14. The medium of claim 11, wherein in response to the battery charge capacity of the battery being a different battery charge capacity than the battery charge capacities in the second subset of ranked battery charge capacities, charge the battery of the computing device.

15. The medium of claim 11, wherein the processing resource is to:
charge the battery of the computing device for a predetermined amount of time; and
after the predetermined amount of time, stop charging the battery and determine the battery charge capacity of the battery of the computing device.
